(19) United States
(12) Patent Application Publication
(10) Pub. No.: US 2014/0023783 A1
(43) Pub. Date: Jan. 23, 2014

(54) APPARATUS FOR MANUFACTURING GRAPHENE FILM AND METHOD FOR MANUFACTURING GRAPHENE FILM

(71) Applicant: Jong-hyuk Yoon, Changwon-city (KR)

(72) Inventor: Jong-hyuk Yoon, Changwon-city (KR)

(73) Assignee: SAMSUNG TECHWIN CO., LTD., Changwon-city (KR)

(21) Appl. No.: 14/005,670

(22) PCT Filed: Mar. 14, 2012
(86) PCT No.: PCT/KR2012/001829

§ 371 Date: Oct. 9, 2013

(30) Foreign Application Priority Data
Mar. 17, 2011 (KR) 10-2011-0023828
Mar. 9, 2012 (KR) 10-2012-0024453

(51) Int. Cl. C23C 16/26

(52) U.S. Cl. CPC C23C 16/26
USPC 427/249.1; 118/725

(57) ABSTRACT

Provided is a graphene film manufacturing apparatus including a source fluid supply unit for supplying a source fluid containing carbon; a gas discharge unit for receiving the source fluid from the source fluid supply unit, thermally decomposing the source fluid into a gas, and discharging the gas; a catalyst substrate disposed to contact the gas discharged from the gas discharge unit, and a heating device disposed to locally heat a region of the catalyst substrate that contacts the discharged gas.

### TECHNICAL FIELD

The present invention relates to an apparatus and method for manufacturing a graphene film, and more particularly, an apparatus and method for manufacturing a graphene film, which are capable of easily improving process convenience and characteristics of a graphene film.

### BACKGROUND ART

Graphene is a conductive material having a thickness equal to that of an atomic layer, in which carbon atoms are two-dimensionally arranged in a honeybee shape. Graphite is obtained when carbon atoms are three-dimensionally stacked, a carbon nanotube is obtained when carbon atoms are one-dimensionally rolled in a column shape, and fullerene having a 0-dimensional structure is formed when carbon atoms are arranged in a ball shape. Graphene is formed of only carbon and is thus very structurally and chemically stable.

Since in graphene, electrons near a Fermi level have a very small effective mass, the speed of electron mobility is substantially the same as the speed of light. Thus, much attention has been paid to graphene as a next-generation element since graphene has high electrical properties. Also, graphene has a thickness that is equal to that of a carbon atom layer and is thus expected to be applied to ultra-high speed and ultra-thin film electronic devices.

In particular, display devices have recently been replaced with flat panel display devices. In general, most flat panel display devices use a transparent electrode. An indium tin oxide (ITO) which is a representative example of a material used to form a transparent electrode is expensive and difficult to form. Thus, using of the ITO is limited and the ITO is not easy to be applied and particularly to, a flexible display device. In contrast, graphene is expected to have not only high elasticity, flexibility, and transparency but also be synthesized and patterned in a relatively simple way. Accordingly, research has been conducted on producing graphene.

However, although graphene has high electrical/mechanical/chemical properties, graphene is difficult to form and is thus difficult to form at a large scale. Thus, there are restrictions to industrially applying graphene. Also, when graphene is formed using a chemical reduction method that enables a mass production, the quality of the graphene is remarkably low.

### DETAILED DESCRIPTION OF THE INVENTION

### Technical Problem

The present invention provides an apparatus and method for manufacturing a graphene film, which are capable of easily improving process convenience and characteristics of a graphene film.

### Technical Solution

According to an aspect of the present invention, an apparatus for manufacturing a graphene film includes a source fluid supply unit for supplying a source fluid containing carbon; a gas discharge unit for receiving the source fluid from the source fluid supply unit, thermally decomposing the source fluid into a gas, and discharging the gas; a catalyst substrate disposed to contact the gas discharged from the gas discharge unit; and a heating device disposed to locally heat at least a region of the catalyst substrate that contacts the discharged gas.

The apparatus may further include a fluid flow rate controller disposed at one end of the source fluid supply unit to control a flow rate of the source fluid supplied to the gas discharge unit from the source fluid supply unit.

The source fluid may further include an inert gas and hydrogen gas.

The gas discharge unit may include a storage member for containing the source fluid; a heating member disposed at external sides of the storage member and configured to thermally decompose the source fluid; and a nozzle member connected to the storage member and configured to discharge the thermally decomposed gas.

The gas discharge unit may extend to have a width corresponding to a width of a side of the catalyst substrate.

The heating device may be disposed facing a surface opposite to a surface of the catalyst substrate that faces the gas discharge unit.

The heating device may be disposed between the gas discharge unit and the catalyst substrate.

The heating device may be disposed at one end of the gas discharge unit.

The apparatus may further include a housing for accommodating the gas discharge unit and at least a region of the catalyst substrate that contacts the discharged gas.

The apparatus may further include an exhaust device connected to the housing.

The catalyst substrate may be provided in a roll-to-roll manner.

The gas discharge unit may discharge the gas while being moved in one direction.

According to another aspect of the present invention, a method of manufacturing a graphene film includes receiving a source fluid containing carbon, thermally decomposes the source fluid into a gas, and discharging the gas; and causing the discharged gas to contact and react with a catalyst substrate. The causing of the discharged gas to contact the catalyst substrate includes locally heating the catalyst substrate that contacts the discharged gas.

The causing of the discharged gas to contact and react with the catalyst substrate is continuously performed while the catalyst substrate or the gas discharge unit is moved.

### Advantageous Effects

According to the present invention, an apparatus and method for manufacturing a graphene film are capable of easily improving process convenience and characteristics of a graphene film.

### DESCRIPTION OF THE DRAWINGS

FIG. 1 is a schematic perspective view of an apparatus for manufacturing a graphene film according to an embodiment of the present invention.

FIG. 2 is a cross-sectional view taken along line II-II of FIG. 1.

FIG. 3 is a schematic perspective view of an apparatus for manufacturing a graphene film according to another embodiment of the present invention.

FIG. 4 is a cross-sectional view taken along line IV-IV of FIG. 3.

FIG. 5 is a schematic perspective view of an apparatus for manufacturing a graphene film according to another embodiment of the present invention.

FIG. 6 is a schematic perspective view of an apparatus for manufacturing a graphene film according to another embodiment of the present invention.

### MODE OF THE INVENTION

Hereinafter, the structure and operations of the present invention will be described in detail with reference to exemplary embodiments of the present invention illustrated in the appended drawings.

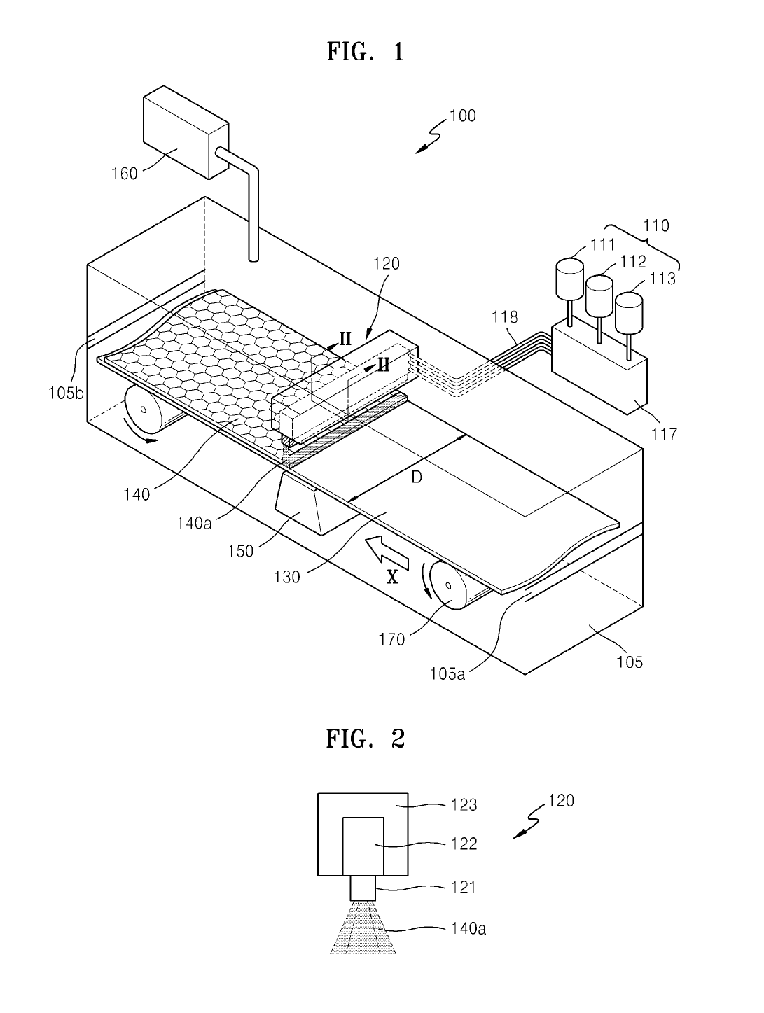

FIG. 1 is a schematic perspective view of a graphene film manufacturing apparatus 100 according to an embodiment of the present invention. FIG. 2 is a cross-sectional view taken along line II-II of FIG. 1.

Referring to FIGS. 1 and 2, the graphene film manufacturing apparatus 100 includes a source fluid supply unit 110, a gas discharge unit 120, a catalyst substrate 130, a heating device 150, and a housing 105.

The source fluid supply unit 110 includes a plurality of fluid supply members 111, 112, and 113 configured to supply different fluids. The plurality of fluid supply members 111, 112, and 113 supply a carbon supply source fluid and an inert gas. As the carbon supply source fluid, CH₄, C₂H₆, C₃H₆, CO, C₂H₅, or other various fluids containing carbon may be used. As the inert gas, N₂, Ar, He, or other various gases may be used. Also, the fluid supply members 111, 112, and 113 may supply hydrogen gas.

The gas discharge unit 120 may be supplied the carbon supply source fluid and the inert gas from the source fluid supply unit 110, thermally decomposes the carbon supply source fluid into a gaseous form, and discharge a decomposed fluid 140a toward the catalyst substrate 130. Specifically, the gas discharge unit 120 is connected to the source fluid supply unit 110 via connection pipes 118. A fluid flow rate controller 117 is disposed at an end of the source fluid supply unit 110, and may easily control the amount of a fluid supplied to the gas discharge unit 120 from the source fluid supply unit 110 by using the fluid flow rate controller 117.

The gas discharge unit 120 includes a nozzle member 121, a storage member 122, and a heating member 123. A gas supplied from the source fluid supply unit 110 via the connection pipes 118 arrives at the storage member 122.

The heating member 123 is disposed around the storage member 122. The heating member 123 heats a fluid contained in the storage member 122, i.e., a carbon supply source fluid, to be decomposed. For example, when the source fluid supply unit 110 uses CH₄ gas as the carbon supply source fluid, the heating member 123 heats the CH₄ gas in the storage member 122 such that the CH₄ gas is decomposed into a carbon component and a hydrogen component. The heating member 123 may use various types of heating sources, e.g., a halogen lamp, infrared rays, etc., without restrictions. In particular, the heating member 123 may include a heating source for supplying heat having a temperature at which the carbon supply source fluid supplied from the source fluid supply unit 110 may be decomposed, e.g., about 800 to 1000° C. However, the present invention is not limited thereto and heats of various temperatures may be supplied from a heating source. That is, a temperature of heat supplied from a heating source may be determined by the type or thickness of the catalyst substrate 130. Specifically, when the thickness of the catalyst substrate 130 is several hundreds of nanometers or less, the temperature of heat supplied from a heating source may be about 200 to 400° C.

For effective thermal decomposing, the heating member 123 may be formed to encompass the storage member 222.

The catalyst substrate 130 is disposed below the gas discharge unit 120. The catalyst substrate 130 may contain at least one selected from the group consisting of copper (Cu), nickel (Ni), cobalt (Co), iron (Fe), platinum (Pt), gold (Au), aluminum (Al), chromium (Cr), magnesium (Mg), manganese (Mn), molybdenum (Mo), rhodium (Rh), silicon (Si), tantalum (Ta), titanium (Ti), tungsten (W), etc. However, the present invention is not limited thereto and the catalyst substrate 130 may be formed of various metals, a metal alloy, a ceramic material having lattice intervals similar to those of graphene, or hexagonal boron nitride (h-BN). The catalyst substrate 130 has a width D.

The decomposed fluid 140a containing carbon is discharged toward the catalyst substrate 130 via the nozzle member 121. Consequently, the decomposed fluid 140a discharged via the nozzle member 121 contacts the catalyst substrate 130. Thus, the carbon reacts with the catalyst substrate 130 and is then cooled to be crystallized, thereby forming the graphene film 140. To efficiently form the graphene film 140, the nozzle member 121 may linearly extend to have a width corresponding to at least the width D of the catalyst substrate 130.

In this case, in order to effectively form the graphene film 140, the heating device 150 configured to heat the catalyst substrate 130 is disposed below the catalyst substrate 130. The heating device 150 heats the catalyst substrate 130 to accelerate the reaction between the fluid 140a and the catalyst substrate 130 when the decomposed fluid 140a contacts the catalyst substrate 130.

In other words, the heating device 150 is disposed to have a width and at a location sufficiently to heat at least a region that contacts the decomposed fluid 140a among regions of the catalyst substrate 130 but the present invention is not limited thereto. That is, the heating device 150 may accelerate the reaction of the fluid 140a with the catalyst substrate 130 by heating a region of the catalyst substrate 130 to contact the decomposed fluid 140a beforehand. To this end, the width of the heating device 150 may be increased sufficiently to heat a region of the catalyst substrate 130 to contact the decomposed fluid 140a beforehand.

To effectively continuously form the graphene film 140, the catalyst substrate 130 may be continuously provided. Specifically, the catalyst substrate 130 is continuously moved in a direction indicated by an arrow X in FIG. 1 (hereinafter referred to as ‘the direction X’) by using rollers 170 disposed below the catalyst substrate 130. The catalyst substrate 130 moved in the direction X sequentially contacts the decomposed fluid 140a discharged from the gas discharge unit 120. Then, the graphene film 140 is formed on an upper surface of the catalyst substrate 130 as described above. In particular, the decomposed fluid 140a passes through the gas discharge unit 120 and the heating device 150 and is then cooled right after the decomposed fluid 140a, which is generated as the catalyst substrate 130 is continuously moved in the direction X, reacts with the catalyst substrate 130, thereby reducing a time needed to form the graphene film 140.

The housing 105 is formed such that at least the gas discharge unit 120 and the catalyst substrate 130 contact to encompass a region on which the graphene film 140 is to be formed. In the housing 105, the gas discharge unit 120, the heating device 150, and the rollers 170 may be disposed. Also, the catalyst substrate 130 is disposed in the housing 105. The housing 105 includes an entrance 105a and an exit 105b configured to be opened and closed so that the catalyst substrate 130 may be continuously moved in the direction X. Due to the structure of the housing 105, gases remaining after the graphene film 140 is formed are prevented from leaking outside the housing 105.

The inside of the housing 105 may be maintained in an atmospheric pressure state. However, the present invention is not limited thereto and the inside of the housing 105 may be maintained in a vacuum state or a low-pressure state to prevent the remaining gases from leaking and to efficiently manage processes.

An exhaust device 160 is disposed to be connected to the housing 105. When the exhaust device 160 is used, the gases remaining after the graphene film 140 is formed may be easily exhausted to prevent impurity gases from being mixed with the gases during the continuous formation of the graphene film 140 and easily prevent the gases from leaking outside the housing 105.

The graphene film 140 formed on the catalyst substrate 130 may be used for various purposes, and may be separated from the catalyst substrate 130 by etching or the like.

In the current embodiment, the graphene film manufacturing apparatus 100 heats a carbon supply source gas to be thermally decomposed using the heating member 123 included in the gas discharge unit 120, and causes the decomposed fluid 140a to contact the catalyst substrate 130. Since the housing 105 is locally heated to thermally decompose the carbon supply source gas without heating the entire space of the housing 105, the graphene film 140 may be efficiently manufactured.

Also, since the catalyst substrate 130 is provided in a roll-to-roll manner, the graphene film 140 may be easily continuously manufactured. In particular, since the carbon supply source gas is thermally decomposed to contact the catalyst substrate 130, the entire catalyst substrate 130 need not be heated at a high temperature, e.g., 800 to 1000° C., at which a carbon supply source is thermally decomposed. Consequently, the fluid 140a and the catalyst substrate 130 are continuously cooled to crystallize the carbon right after the fluid 140a and the catalyst substrate 130 react with each other, thereby remarkably reducing a time needed to manufacture the graphene film 140.

In this case, the heating device 150 is disposed to correspond to a region of the catalyst substrate 130 that contacts the fluid 140a, thereby accelerating the reaction between the catalyst substrate 130 and the fluid 140a. In particular, the catalyst substrate 130 is locally heated to improve process efficiency. That is, when the catalyst substrate 130 is locally heated, the duration of a crystallization process using cooling, which needs a considerable time during the manufacture of the graphene film 140, is remarkably reduced.

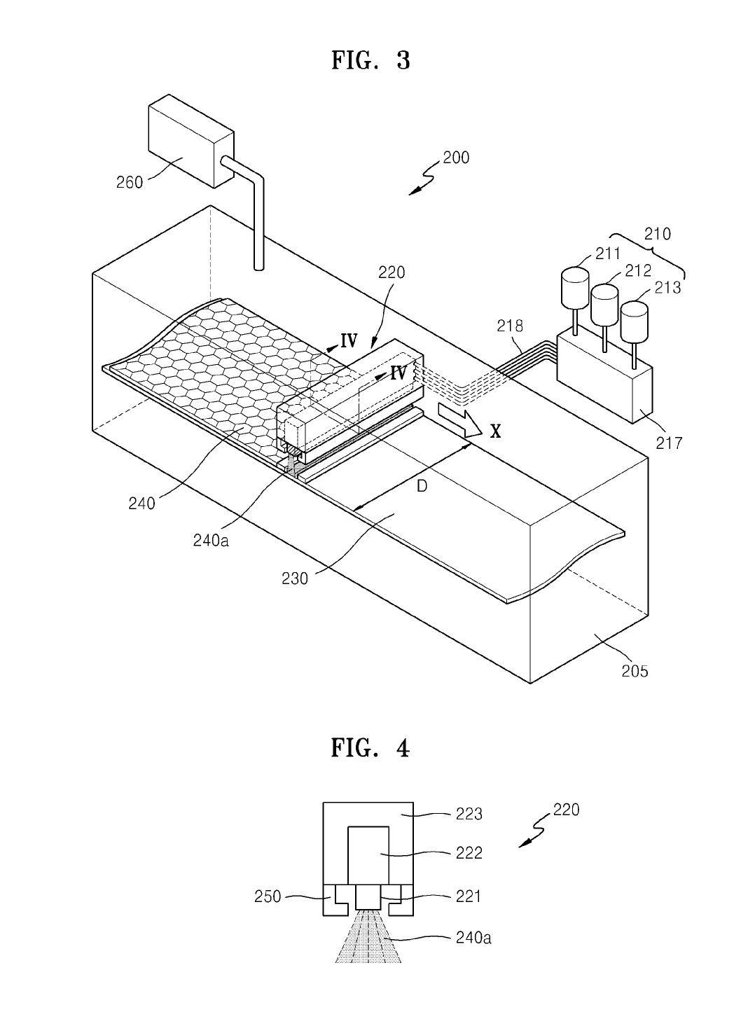

FIG. 3 is a schematic perspective view of a graphene film manufacturing apparatus 200 according to another embodiment of the present invention. FIG. 4 is a cross-sectional view taken along line IV-IV of FIG. 3.

Referring to FIGS. 3 and 4, the graphene film manufacturing apparatus 200 includes a source fluid supply unit 210, a gas discharge unit 220, a catalyst substrate 230, a heating device 250, and a housing 205.

The source fluid supply unit 210 includes a plurality of gas supply members 211, 212, and 213 configured to supply different gases.

The gas discharge unit 220 is supplied a carbon supply source fluid and an inert gas from the source fluid supply unit 210, thermally decomposes the carbon supply source fluid, and discharges a decomposed fluid 240a toward the catalyst substrate 230. Specifically, the gas discharge unit 220 is connected to the source fluid supply unit 210 via connection pipes 218. A fluid flow rate controller 217 may be disposed at one end of the source fluid supply unit 210 via the fluid flow rate controller 217 so as to easily control the amount of a gas supplied to the gas discharge unit 220 from the source fluid supply unit 210.

The gas discharge unit 220 includes a nozzle member 221, a storage member 222, and a heating member 223. The gas supplied from the source fluid supply unit 210 via the connection pipes 218 arrives at the storage member 222.

The heating member 223 is disposed around the storage member 222. The heating member 223 heats a gas contained in the storage member 222, i.e., a carbon supply source fluid, to be decomposed. For example, when the source fluid supply unit 210 uses CH₄ as the carbon supply source fluid, the heating member 223 heats CH₄ fluid contained in the catalyst substrate 230 to be decomposed into a carbon component and a hydrogen component. The heating member 223 may use various types of heating sources, e.g., a halogen lamp, infrared rays, etc., without restrictions. In particular, the heating member 223 may include a heating source for supplying heat having a temperature at which the carbon supply source fluid supplied from the source fluid supply unit 210 may be decomposed, e.g., about 800 to 1000° C.

However, the present invention is not limited thereto and heats of various temperatures may be supplied from a heating source. That is, a temperature of heat supplied from a heating source may be determined by the type or thickness of the catalyst substrate 230. Specifically, when the thickness of the catalyst substrate 230 is several hundreds of nanometers or less, the temperature of heat supplied from a heating source may be about 200 to 400° C.

The catalyst substrate 230 is disposed below the gas discharge unit 220. The catalyst substrate 230 has a width D.

The decomposed fluid 240a, and particularly, the carbon-based fluid 240a is discharged in a gaseous form toward the catalyst substrate 230 via the nozzle member 221. Consequently, the decomposed fluid 240a discharged via the nozzle member 221 contacts the catalyst substrate 230. Thus, the carbon in the decomposed fluid 240a reacts with the catalyst substrate 230 and is then cooled to be crystallized, thereby forming a graphene film 240. To efficiently form the graphene film 240, the nozzle member 221 may linearly extend to have a width corresponding to at least the width D of the catalyst substrate 230.

In this case, in order to effectively form the graphene film 240, the heating device 250 configured to heat the catalyst substrate 230 is disposed on the catalyst substrate 230. That is, the heating device 250 is disposed between the catalyst substrate 230 and the gas discharge unit 220. The heating device 250 may be disposed at one end of the gas discharge unit 220.

The heating device 250 heats the catalyst substrate 230 beforehand to accelerate the fluid 240a, which is decomposed when the decomposed fluid 240a contacts the catalyst substrate 230, to react with the catalyst substrate 230.

That is, the heating device 250 is disposed to have a width and at a location sufficiently to heat at least a region that contacts the decomposed fluid 240a among regions of the catalyst substrate 230. In other words, the heating device 250 may be disposed at one end of the gas discharge unit 220 and in a size that does not exceed the width of the gas discharge unit 220. As illustrated in FIG. 4, the heating device 250 may be formed to be connected to one end of the storage member 222 and to be spaced from the nozzle member 221.

To effectively continuously form the graphene film 240, the gas discharge unit 220 is moved with respect to the catalyst substrate 230. That is, the gas discharge unit 220 is continuously moved in a direction indicated with an arrow X in FIG. 3 (hereinafter referred to as the ‘direction X’). The fluid 240a discharged from the gas discharge unit 220 moved in the direction X sequentially contacts the catalyst substrate 230.

Consequently, the graphene film 240 is continuously formed on an upper surface of the catalyst substrate 230. In particular, the decomposed fluid 240a, which is generated as the gas discharge unit 220 is continuously moved in the direction X, passes through the gas discharge unit 220 and the heating device 250 and is then cooled right after the decomposed fluid 240a reacts with the catalyst substrate 230, thereby reducing a time needed to form the graphene film 240.

The housing 205 is formed such that at least the gas discharge unit 220 and the catalyst substrate 230 contact to encompass a region on which the graphene film 240 is formed. In the housing 205, the gas discharge unit 220, the heating device 250, and the catalyst substrate 230 may be disposed. Due to the structure of the housing 205, gases remaining and impurity gases after the graphene film 240 is manufactured are prevented from leaking outside the housing 205.

The inside of the housing 205 may be maintained in an atmospheric pressure state. However, the present invention is not limited thereto and the inside of the housing 105 may be maintained in a vacuum state or a low-pressure state to prevent the remaining gases from leaking and to efficiently manage processes.

An exhaust device 260 is disposed to be connected to the housing 205. When the exhaust device 260 is used, gases remaining after the graphene film 240 is formed may be easily exhausted to prevent impurity gases from being mixed with the gases during continuous formation of the graphene film 240 and to easily prevent the gases from leaking outside the housing 205.

In the current embodiment, the graphene film manufacturing apparatus 200 heats a carbon supply source fluid to be thermally decomposed using the heating member 223 included in the gas discharge unit 220 and causes the decomposed fluid 240a to contact the catalyst substrate 230. Since the housing 205 is locally heated to thermally decompose the carbon supply source gas without heating the entire space of the housing 105, the graphene film 240 may be efficiently manufactured.

Also, since the manufacturing process is performed while the gas discharge unit 220 is moved, the graphene film 240 may be easily continuously formed. In particular, since the carbon supply source gas is thermally decomposed to contact the catalyst substrate 230, the entire catalyst substrate 230 need not be heated at a high temperature, e.g., 800 to 1000° C., at which a carbon supply source is thermally decomposed. Consequently, the decomposed fluid 240a and the catalyst substrate 230 are continuously cooled to crystallize the carbon right after the decomposed fluid 240a and the catalyst substrate 230 react with each other, thereby remarkably reducing a time needed to manufacture the graphene film 240.

In this case, the heating device 150 is disposed to correspond to a region of the catalyst substrate 230 that contacts the fluid 240a, thereby accelerating the reaction between the catalyst substrate 230 and the decomposed fluid 240a. In particular, the catalyst substrate 130 is locally heated to improve process efficiency. That is, when the catalyst substrate 230 is locally heated, the duration of a crystallization process using cooling, which needs a considerable time during the manufacture of the graphene film 240, is remarkably reduced.

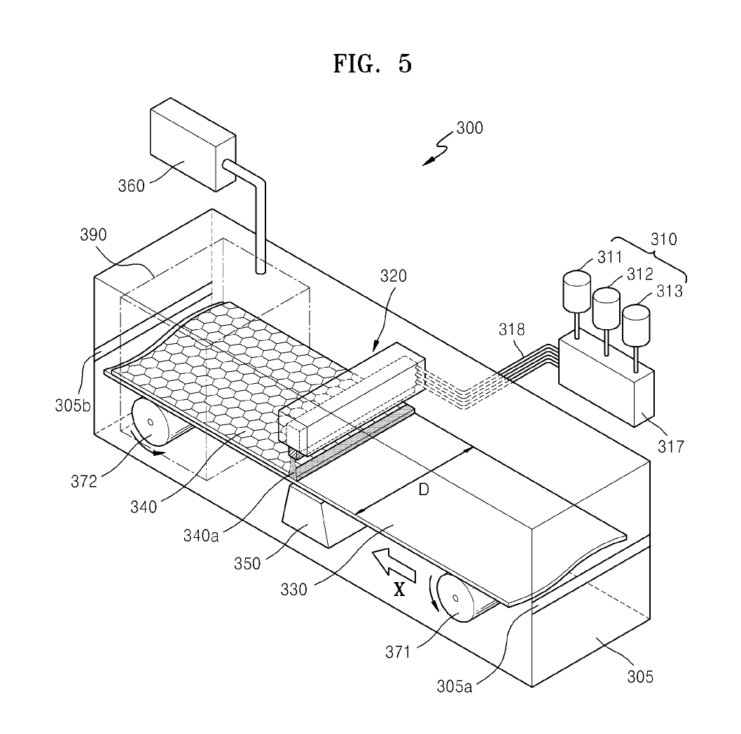

FIG. 5 is a schematic perspective view of a graphene film manufacturing apparatus 300 according to another embodiment of the present invention.

Referring to FIG. 5, the graphene film manufacturing apparatus 300 includes a source fluid supply unit 310, a gas discharge unit 320, a catalyst substrate 330, a heating device 350, a housing 305, and a cooling unit 390.

In the current embodiment, the graphene film manufacturing apparatus 300 is substantially the same as the graphene film manufacturing apparatus 100 of FIGS. 1 and 2. For convenience of explanation, the graphene film manufacturing apparatus 300 will be described focusing on the differences between the graphene film manufacturing apparatus 300 and the graphene film manufacturing apparatus 100 of FIGS. 1 and 2.

The source fluid supply unit 310 includes a plurality of fluid supply members 311, 312, and 313. The plurality of fluid supply members 311, 312, and 313 provide a carbon supply source fluid and an inert gas.

The gas discharge unit 320 is supplied the carbon supply source fluids and the inert gas from the source fluid supply unit 310, thermally decomposes the carbon supply source fluids into a gaseous form, and discharges a decomposed fluid 340a in the gaseous form toward the catalyst substrate 330.

Although not shown, the gas discharge unit 320 according to the current embodiment includes a nozzle member, a storage member, and a heating member, similar to the gas discharge unit 120 of FIGS. 1 and 2.

The catalyst substrate 330 is disposed facing the gas discharge unit 320. That is, the gas discharge unit 320 and the catalyst substrate 330a are disposed to cause a gas discharged from the gas discharge unit 320 to flow toward the catalyst substrate 330.

The decomposed fluid 340a containing carbon flows toward the catalyst substrate 330 via the gas discharge unit 320. Consequently, the decomposed fluid 340a discharged via the gas discharge unit 320 contacts the catalyst substrate 330. Thus, the carbon reacts with the catalyst substrate 330 and is then crystallized to form a graphene film 340.

In this case, in order to effectively form the graphene film 340, the heating device 350 configured to heat the catalyst substrate 330 is disposed below the catalyst substrate 330. The heating device 350 heats the catalyst substrate 330 to accelerate the reaction between the fluid 340a and the catalyst substrate 330 when the decomposed fluid 340a contacts the catalyst substrate 330.

To effectively continuously form the graphene film 340, the catalyst substrate 330 is continuously provided. That is, the catalyst substrate 330 is continuously moved in a direction indicated with an arrow X in FIG. 5 (hereinafter referred to as the ‘direction X’) using a first roller 371 and a second roller 372 disposed below the catalyst substrate 330. The catalyst substrate 330 moved in the direction X sequentially the decomposed fluid 340a discharged from the gas discharge unit 320. Then, the graphene film 340 is formed on an upper surface of the catalyst substrate 330 as described above.

The cooling unit 390 is disposed apart from the gas discharge unit 320. The cooling unit 390 is disposed such that the graphene film 340 formed on the catalyst substrate 330 is effectively grown. To this end, the cooling unit 390 may use various cooling means, and cooling water may be caused to flow through the cooling unit 390 or a cooling gas may be injected into a region of the cooling unit 390. When a method using cooling water is employed, a cooling process may be performed using the second roller 372 by injecting cooling water into the second roller 372. In this case, the cooling unit 390 may not additionally need a section, such as an additional case, which sets a boundary between the cooling unit 390 and the outside. In contrast, when a method using a cooling gas is employed, the cooling unit 390 needs a predetermined section. That is, the cooling unit 390 may be formed to have a section indicated by a dotted line as illustrated in FIG. 5, and a cooling gas may be injected into the cooling unit 390.

Although FIG. 5 illustrates that the cooling unit 390 is disposed in parallel with a region in which the gas discharge unit 320 is disposed, the present invention is not limited thereto. For example, in order to effectively separate the cooling unit 390 and the gas discharge unit 320 from each other, the cooling unit 390 and the gas discharge unit 320 may be disposed in inversely parallel with each other so that the catalyst substrate 330 passing through the gas discharge unit 320 may be moved in a path that is bent at a predetermined angle. An arrangement of the cooling unit 390 and the gas discharge unit 320 may be determined in various ways, based on process conditions.

The housing 305 is formed such that at least the gas discharge unit 320 and the catalyst substrate 330 contact to encompass a region on which the graphene film 340 is to be formed. The housing 305 includes an entrance 305a and an exit 305b configured to be opened and closed. An exhaust device 360 is disposed to be connected to the housing 305.

In particular, when the cooling unit 390 and the gas discharge unit 320 are disposed in inversely parallel to be effectively separated from each other as described above, the exhaust device 360 is separated from the region in which the cooling unit 390 is disposed and is connected to only a region adjacent to the region in which the gas discharge unit 320 is disposed, i.e., a region in which graphene is synthesized.

In the graphene film manufacturing apparatus 300 according to the current embodiment, the graphene film 340 formed using the gas discharge unit 320 and the catalyst substrate 330 is sequentially cooled by the cooling unit 390 to be efficiently grown, thereby remarkably reducing a time needed to complete the graphene film 340. Also, the thickness uniformity of the completed graphene film 340 is improved. Also, during the manufacture of the graphene film 340, the graphene film 360 is directly cooled by the cooling unit 390 and a subsequent process, e.g., an etching process or a transfer process, may thus be directly performed without a pause.

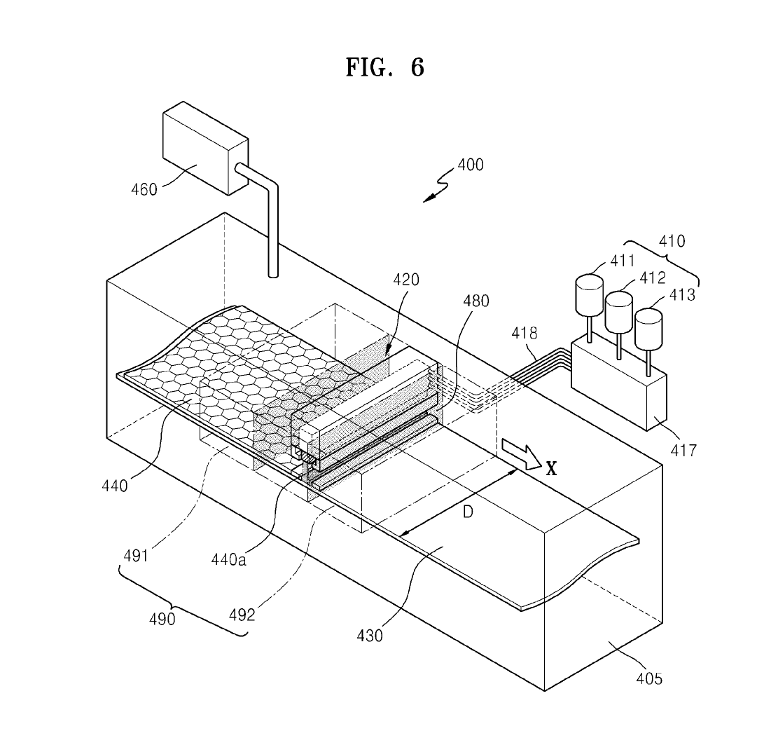

FIG. 6 is a schematic perspective view of a graphene film manufacturing apparatus 400 according to another embodiment of the present invention.

Referring to FIG. 6, the graphene film manufacturing apparatus 400 includes a source fluid supply unit 410, a gas discharge unit 420, a catalyst substrate 430, a heating device 450, and a housing 405.

The graphene film manufacturing apparatus 400 according to the current embodiment is similar to the graphene film manufacturing apparatus 200 of FIGS. 3 and 4. For convenience of explanation, the graphene film manufacturing apparatus 400 will be described focusing on the differences between graphene film manufacturing apparatus 400 and graphene film manufacturing apparatus 200.

A source fluid supply unit 410 includes a plurality of gas supply members 411, 412, and 413 configured to supply different gases.

The gas discharge unit 420 is supplied a carbon supply source fluid and an inert gas from the source fluid supply unit 410, thermally decomposes the carbon supply source fluid, and discharges a decomposed fluid 440a toward the catalyst substrate 430.

Although not shown, the gas discharge unit 420 according to the current embodiment includes a nozzle member, a storage member, and a heating member, similar to the gas discharge unit 320 of FIGS. 3 and 4.

The catalyst substrate 430 is disposed below the gas discharge unit 420, and has a width D.

The decomposed fluid 440a, and particularly, the carbon-based fluid 440a flows in a gaseous form toward catalyst substrate 430 via the gas discharge unit 420. Consequently, the decomposed fluid 440a discharged from the gas discharge unit 420 contacts the catalyst substrate 430. Thus, the carbon contained in the decomposed fluid 440a reacts with the catalyst substrate 430 and is then cooled to be crystallized, thereby forming a graphene film 440.

To effectively continuously form the graphene film 440, the gas discharge unit 420 is moved with respect to the catalyst substrate 430. That is, the gas discharge unit 420 is continuously moved in a direction indicated with an arrow X in FIG. 6 (hereinafter referred to as the ‘direction X’). The decomposed fluid 440a discharged from the gas discharge unit 420 moved in the direction X sequentially contacts the catalyst substrate 430. Consequently, the graphene film 440 is continuously formed on an upper surface of the catalyst substrate 430. However, the present invention is not limited thereto and the gas discharge unit 420 may be formed to make a linear movement in both directions. That is, the gas discharge unit 420 may be formed to be moved in the direction X and a direction opposite to the direction X. In this case, the graphene film 440 may be manufactured in various ways. For example, one graphene film 440 may be manufactured in the direction X and another graphene film 440 may be manufactured in the direction opposite to the direction X. In this case, when the graphene film 440 is produced at a large scale, a time needed to move the gas discharge unit 420 may be reduced, thereby reducing a time to perform the process.

A cooling unit 490 is disposed apart from the gas discharge unit 420. The cooling unit 490 is disposed such that the graphene film 440 formed on the upper surface of the catalyst substrate 430 is effectively grown.

Specifically, the cooling unit 490 includes a first cooling member 491 and a second cooling member 492. The first cooling member 491 is disposed at one side of the gas discharge unit 420 to be separated from the gas discharge unit 420. The second cooling member 492 is disposed at another side of the gas discharge unit 420 to be separated from the gas discharge unit 420. The first and second cooling member 491 and 492 may be selectively operated. That is, when the graphene film 440 is formed while the gas discharge unit 420 is moved in the direction X as illustrated in FIG. 6, only the first cooling member 491 may be operated. Although not shown, when the graphene film 440 is formed while the gas discharge unit 420 is moved in the direction opposite to the direction X, only the second cooling member 492 may be operated. That is, the cooling members 491 and 492 of the cooling unit 490 may be operated to cool the graphene film 440 formed on the catalyst substrate 430.

The cooling unit 490 may use various cooling means. For example, cooling water may be caused to flow into the cooling unit 490 or a cooling gas may be injected into a region of the cooling unit 490.

The cooling unit 490 is moved together with the gas discharge unit 420. That is, the cooling unit 490 is disposed to make a linear movement in the direction X or the direction opposite to the direction X, similar to the gas discharge unit 420.

The cooling unit 490 and the gas discharge unit 420 are separated by a barrier wall 480 so that a heating process performed by the gas discharge unit 420 may not be influenced by the cooling means, e.g., a cooling gas or cooling water, which is employed by the cooling unit 490. To this end, the barrier wall 480 is formed of a material capable of blocking heat. Also, in order to effectively block heat, the barrier wall 480 may be disposed to encompass the gas discharge unit 420.

The housing 405 is formed such that at least the gas discharge unit 420 and the catalyst substrate 430 contact to encompass a region on which the graphene film 440 is to be formed. In the housing 405, the gas discharge unit 420, the heating device 450, the catalyst substrate 430, and the cooling unit 490 may be disposed. The exhaust device 460 is disposed to be connected to the housing 405.

Although not shown, the gas discharge unit 420 may be moved as illustrated in FIG. 6 while the catalyst substrate 330 is moved in the roll-to-roll manner illustrated in FIG. 5. In this case, one of the cooling unit 390 and the cooling unit 490 according to the previous embodiments may be used.

In the graphene film manufacturing apparatus 400 according to the current embodiment, the graphene film 440 formed using the gas discharge unit 420 and the catalyst substrate 430 are sequentially cooled by the cooling unit 490 to be efficiently grown, thereby remarkably reducing a time needed to complete the graphene film 340. Also, the thickness uniformity of the completed graphene film 440 may be improved. Also, since the graphene film 440 is directly cooled by the cooling unit 490, a subsequent process, e.g., an etching process or a transfer process, may be directly performed without a pause.

In the above one or more embodiments, it has been described above that the graphene film manufacturing apparatuses 100, 200, 300, and 400 each include only one gas discharge unit, i.e., they include the gas discharge units 120, 220, 320, and 420, respectively. However, the present invention is not limited thereto, and in order to efficiently perform the process, the graphene film manufacturing apparatuses 100, 200, 300, and 400 may each include a plurality of gas discharge units according to process conditions and other design conditions.

While this invention has been particularly shown and described with reference to exemplary embodiments thereof, it will be understood by those of ordinary skill in the art that various changes in form and details may be made therein without departing from the spirit and scope of the invention as defined by the appended claims.

### EXPLANATION OF REFERENCE NUMERALS

100, 200, 300, 400: graphene film manufacturing apparatus
105, 205, 305, 405: housing
110, 210, 310, 410: source fluid supply unit
117, 217, 317, 417: fluid flow rate controller
120, 220, 320, 420: gas discharge unit
121, 221, 321, 421: nozzle member
122, 222, 322, 422: storage member
123, 223, 323, 423: heating member
130, 230, 330, 430: catalyst substrate
140, 240, 340, 440: graphene film
150, 250, 350, 450: heating device
160, 260, 360, 460: exhaust device
170, 371, 372: roller
390, 490: cooling unit

1. An apparatus for manufacturing a graphene film, the apparatus comprising:
a source fluid supply unit for supplying a source fluid containing carbon;
a gas discharge unit for receiving the source fluid from the source fluid supply unit, thermally decomposing the source fluid into a gas, and discharging the gas;
a catalyst substrate disposed to contact the gas discharged from the gas discharge unit; and
a heating device disposed to locally heat at least a region of the catalyst substrate that contacts the discharged gas.

2. The apparatus of claim 1, further comprising a fluid flow rate controller disposed at one end of the source fluid supply unit to control a flow rate of the source fluid supplied to the gas discharge unit from the source fluid supply unit.

3. The apparatus of claim 1, wherein the source fluid further comprises an inert gas and hydrogen gas.

4. The apparatus of claim 1, wherein the gas discharge unit comprises:
a storage member for containing the source fluid;
a heating member disposed at external sides of the storage member and configured to thermally decompose the source fluid; and
a nozzle member connected to the storage member and configured to discharge the thermally decomposed gas.

5. The apparatus of claim 1, wherein the gas discharge unit extends to have a width corresponding to a width of a side of the catalyst substrate.

6. The apparatus of claim 1, wherein the heating device is disposed facing a surface opposite to a surface of the catalyst substrate that faces the gas discharge unit.

7. The apparatus of claim 1, wherein the heating device is disposed between the gas discharge unit and the catalyst substrate.

8. The apparatus of claim 7, wherein the heating device is disposed at one end of the gas discharge unit.

9. The apparatus of claim 1, further comprising a housing for accommodating the gas discharge unit and at least a region of the catalyst substrate that contacts the discharged gas.

10. The apparatus of claim 9, further comprising an exhaust device connected to the housing.

11. The apparatus of claim 1, wherein the catalyst substrate is provided in a roll-to-roll manner.

12. The apparatus of claim 1, wherein the gas discharge unit discharges the gas while being moved in one direction.

13. A method of manufacturing a graphene film, the method comprising:
receiving a source fluid containing carbon, thermally decomposes the source fluid into a gas, and discharging the gas; and
causing the discharged gas to contact and react with a catalyst substrate,
wherein the causing of the discharged gas to contact the catalyst substrate comprises locally heating the catalyst substrate that contacts the discharged gas.

14. The method of claim 13, wherein the causing of the discharged gas to contact and react with the catalyst substrate is continuously performed while the catalyst substrate or the gas discharge unit is moved.

15. The apparatus of claim 1, further comprising a cooling unit disposed apart from the gas discharge unit, and configured to cool a region of the catalyst substrate that contacts the discharged gas after a predetermined time.

16. The apparatus of claim 15, wherein the cooling unit performs a cooling operation when a cooling gas is injected into the cooling unit or cooling water flows into the cooling unit.

17. The apparatus of claim 15, wherein the catalyst substrate is provided in a roll-to-roll manner, and
the cooling unit is disposed in a region of the catalyst substrate that becomes far from the gas discharge unit as the catalyst substrate is moved in the roll-to-roll manner.

18. The apparatus of claim 17, wherein the cooling unit comprises a roller for driving the catalyst substrate,
wherein cooling water passes through the roller.

19. The apparatus of claim 17, wherein the cooling unit is disposed in inversely parallel with the gas discharge unit such that the catalyst substrate passes through a region corresponding to the gas discharge unit, is moved in a path that is bent at a predetermined angle, and then passes through the cooling unit.

20. The apparatus of claim 15, wherein the gas discharge unit makes a linear movement, and
the cooling unit is disposed at at least a side of the gas discharge unit, and configured to make a movement together with the gas discharge unit.

21. The apparatus of claim 20, wherein a barrier wall is disposed between the cooling unit and the gas discharge unit to block heat.

22. The apparatus of claim 20, wherein the barrier wall is formed to encompass the gas discharge unit.

23. The apparatus of claim 20, wherein the cooling unit is disposed at both sides of the gas discharge unit.

24. The method of claim 23, after the discharged gas is caused to contact the catalyst substrate, further comprising cooling the region of the catalyst substrate that contacts the discharged gas.
